(19) United States
(12) Patent Application Publication
(10) Pub. No.: US 2009/0134422 A1
(43) Pub. Date: May 28, 2009

(54) LED PACKAGE MODULE AND MANUFACTURING METHOD THEREOF

(76) Inventor: Wen-Jyh SAH, Tainan City (TW)

Correspondence Address: BIRCH STEWART KOLASCH & BIRCH, PO BOX 747, FALLS CHURCH, VA, 22040-0747, US

(21) Appl. No.: 12/274,223

(22) Filed: Nov. 19, 2008

(30) Foreign Application Priority Data
Nov. 23, 2007 (TW) 096144646

(51) Int. Cl. H01L 33/00; H01L 21/00

(52) U.S. Cl. 257/99; 438/26; 257/E33.001; 257/E21.001

(57) ABSTRACT

A light emitting diode (LED) package module includes a substrate, a first LED die, a second LED die, a connecting circuit and a repairing circuit. The first LED die and the second LED die are disposed on the substrate by wire bonding or flip-chip bonding. The second LED die and the first LED die are electrically connected in series through the connecting circuit. The repairing circuit has two first extension portions, which are electrically connected with two electrodes of the first LED die, respectively. A manufacturing method of the LED package module is also disclosed.

### CROSS REFERENCE TO RELATED APPLICATIONS

This Non-provisional application claims priority under 35 U.S.C. §119(a) on Patent Application No(s). 096144646 filed in Taiwan, Republic of China on Nov. 23, 2007, the entire contents of which are hereby incorporated by reference.

### BACKGROUND OF THE INVENTION

1. Field of Invention

The invention relates to a package module and a manufacturing method thereof. More particularly, the invention relates to a light emitting diode (LED) package module and a manufacturing method thereof.

2. Related Art

The light emitting diode (LED), which is different from the conventional incandescent lamp, is a cold light and has the advantages of low power consumption, long lifetime, no warm-up time and fast response time. In addition, the LED has small size and good vibration durability, and it is suitable for mass production, so that the LED can be manufactured as fine or array elements so as to easily match the application requirements. Presently, the LED is widely used in the display apparatus and the indicator of the information, communication and consumption electronic product, so it has become an indispensable important element in our life. Recently, the LED is further used as the light source of the backlight module in the liquid crystal display (LCD), and is gradually replacing the traditional cold cathode fluorescent lamp (CCFL).

The COB (chip on board) package is one of the known LED package methods. In the COB package, the die is directly packaged on the circuit substrate with three basic processes of die attaching, wire bonding and molding.

FIG. 1 is a side view of a conventional LED package module 1, and FIG. 2 is a top view of the conventional LED package module 1. Referring to FIGS. 1 and 2, the LED package module 1 includes a substrate 11, a plurality of LED dies 12, a plurality of wires 13 and a package body 14. In this case, the LED dies 12 are packaged on the substrate 11 by COB technology, and they are connected in series through the wires 13. The package body 14 covers the wires 13 and the LED dies 12 for protecting the junctions between the wires 13 and the LED dies 12.

Regarding to the LED package module 1, since the LED dies 12 are connected in series, only one damaged LED die 12 can fail all of the LED dies 12, and the entire LED package module 1 can not emit light normally. In addition, because the LED dies 12 are packaged in the package body 14, the damaged LED die 12 can not be repaired by rework. Accordingly, one damaged LED die 12 can caused the malfunction of the entire LED package module 1, thereby decreasing the production yield and causing the waste of the material.

Therefore, it is an important subject to provide a LED package module with the repairing function.

### SUMMARY OF THE INVENTION

In view of the foregoing, the present invention is to provide a LED package module with the repairing function.

To achieve the above, the present invention discloses a light emitting diode (LED) package module including a substrate, a first LED die, a second LED die, a connecting circuit and a repairing circuit. The first LED die and the second LED die are disposed on the substrate by wire bonding or flip-chip bonding. The first LED die and the second LED die are electrically connected in series through the connecting circuit. The repairing circuit has two first extension portions, which are electrically connected with two electrodes of the first LED die, respectively.

In addition, the present invention also discloses a manufacturing method of a LED package module. The manufacturing method includes the steps of: forming a connecting circuit on a substrate; forming a repairing circuit, which has two first extension portions, on the substrate; and disposing a first LED die and a second LED die on the substrate by wire bonding or flip-chip bonding. The first LED die and the second LED die are electrically connected in series, and the first extension portions are electrically connected with two electrodes of the first LED die, respectively.

As mentioned above, the LED package module has the repairing circuit for bypassing the damaged LED die, so that the problem of the conventional LED package module that one damaged LED die can fail the entire LED package module can be prevented. In practice, each LED die can be detected through the repairing circuit so as to determine whether the LED die can emit light or not. If it is detected that one LED die is damaged, the extension portions of the repairing circuit corresponding to the damaged LED die are shorted, so that the current can bypass the damaged LED die and the other LED dies can operate normally. Thus, the LED package module with one or few damaged LED dies can still work and will not be regarded as a defect product. Accordingly the present invention can increase the manufacturing yield of the LED package module, reduce the cost and prevent the waste of the material.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a side view of a conventional LED package module;

FIG. 2 is a top view of the conventional LED package module;

FIG. 3 is a top view of a LED package module according to a preferred embodiment of the invention;

FIG. 4 is a top view of another LED package module according to the preferred embodiment of the invention; and

FIG. 5 is a flow chart of a manufacturing method of the LED package module according to the preferred embodiment of the invention.

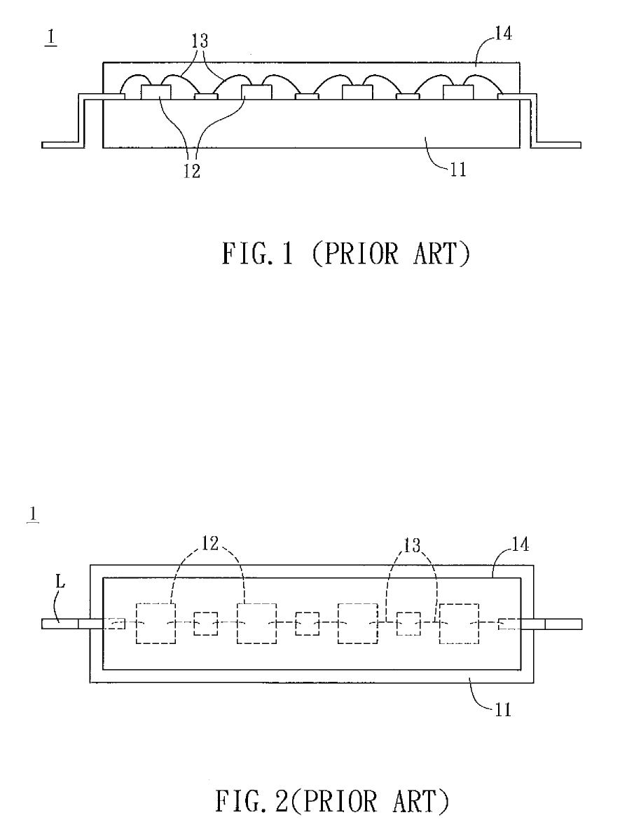

### DETAILED DESCRIPTION OF THE INVENTION

The present invention will be apparent from the following detailed description, which proceeds with reference to the accompanying drawings, wherein the same references relate to the same elements.

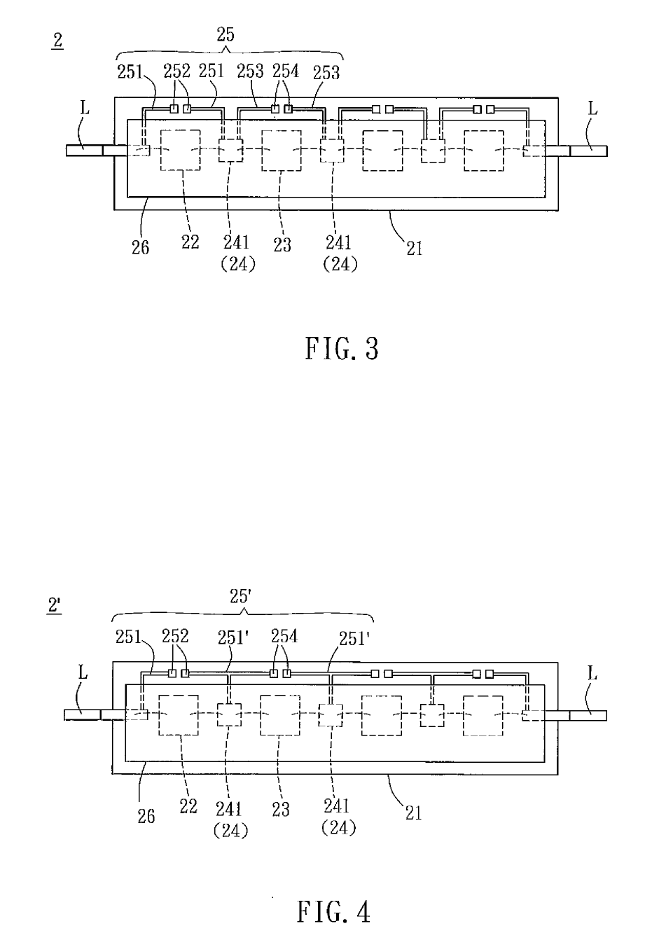

FIG. 3 is a top view of a LED package module 2 according to a preferred embodiment of the invention. With reference to FIG. 3, the LED package module 2 includes a substrate 21, a first LED die 22, a second LED die 23, a connecting circuit 24 and a repairing circuit 25. The LED package module 2 can be used as a light source of a backlight module, an illumination device, a vehicle lamp, an outdoor media board or a light source module of other electronic devices.

The substrate 21 can be a printed circuit substrate, a flexible substrate, a ceramic substrate, a metal substrate or a glass circuit substrate. In the embodiment, the substrate 21 is a printed circuit substrate for example, and the ratio of the length to the width of the substrate 21 is larger than 10.

The first LED die 22 and the second LED die 23 are directly disposed on the substrate 21 by COB (chip on board). For example, the first LED die 22 and the second LED die 23 can be disposed on the substrate 21 by wire bonding or flip-chip bonding. The colors of the emitted lights from the first LED die 22 and the second LED die 23 are, for example but not limited to, white light, red light, blue light, green light or other monochromatic light. Besides, the colors of the emitted lights from the first LED die 22 and the second LED die 23 can be the same or different.

In the embodiment, the connecting circuit 24 includes a plurality of connecting pads 241, which are electrically connected with the circuit layer of the substrate 21. The first LED die 22 and the second LED die 23 are connected with the connecting pads 241 by wire bonding, so that they can be electrically connected in series through the connecting pads 241. As shown in FIG. 3, the LED package module 2 includes, for example, four LED dies, and the LED dies are arranged in a line along a long-axis direction of the substrate 21. However, the number of the LED dies and the arrangement thereof are not limited to this.

The repairing circuit 25 has two first extension portions 251, which are electrically connected with two electrodes of the first LED die 22, respectively, and partially exposed from the package body 26. In the embodiment, the repairing circuit further includes two first repairing pads 252, which are disposed on the first extension portions 251, respectively. As shown in FIG. 3, each first repairing pad 252 is disposed on one end of each first extension portion 251 away from the first LED die 22. In addition, the repairing circuit 25 may further include two second extension portions 253 and two repairing pads 254. The second extension portions 253 are electrically connected with two electrodes of the second LED die 23, respectively, and partially exposed from the package body 26. The second repairing pads 254 are disposed on the second extension portions 253, respectively. As shown in FIG. 3, each second repairing pad 254 is disposed on one end of each second extension portion 253 away from the second LED die 23. To be noted, it is preferred but not necessary to provide the corresponding extension portions for each LED die. Of course, multiple LED dies can commonly have the same extension portions.

In addition, the repairing circuit 25 can be disposed on the substrate 21 before bonding the first LED die 22 and the second LED die 23 to the substrate 21.

In the embodiment, the package body 26 covers the first LED die 22, the second LED die 23 and other LED dies for protecting the electrode junctions and wires of the LED dies. In general, the material of the package body 26 includes a transparent epoxy. In addition, the LED package module 2 further includes a plurality of outer leads L, which electrically connected with the circuit layer of the substrate 21 or the connecting pads 241. The external control signal can be inputted through the outer leads L for controlling the LED des to emit light. Of course, the LED package module 2 may not have the outer leads L, and the substrate 21 thereof is electrically connected with a control chip by SMT (surface mount technology).

The LED package module 2 has the repairing circuit 25 to separately detect the LED dies so as to determine whether each LED die is normal or not. For example it is possible to detect the electric signals of the first repairing pads 252 so as to determine whether the first LED die 22 is normal or not. Once the first LED die 22 is determined as a defect die and the second LED die 23 is determined as a normal die, the first repairing pads 252 are shorted by welding so that the first extension portions 251 of the repairing circuit 25 are connected. Thus, the current will flow through the first extension portions 251, which have smaller resistance, and bypass the first LED die 22. Then, the current can flow to the second LED die 23 to drive the second LED die 23 to emit light. Accordingly, the LED package module 2 can still emit light while one of the LED dies, which are connected in series, is fail. Thus, the LED package module 2 of the invention can reduce the cost and prevent the waste of the material.

In addition, except the above-mentioned welding method, the first extension portions 251 can also be connected by soldering or wire bonding, or they can be connected through a low-resistance element. Alternatively, the first extension portions 251 can be connected by laser welding through a vertical overlap area of the repairing circuit 25. All these method can allow the current bypass the first LED die 22. In addition, the configuration of the low-resistance element can further provide the function of balancing impedance.

FIG. 4 is a top view of another LED package module 2′ according to the preferred embodiment of the invention. With reference to FIG. 4, the difference between the LED package modules 2′ and 2 is in that one of the second extension portions 253 and one of the first extension portions 251 of the repairing circuit 25 in FIG. 3 are combined, so that the extension portion 251′ of the repairing circuit 25′ in FIG. 4 can electrically connected to both of the first repairing pad 252 of the first LED die 22 and the second repairing pad 254 of the second LED die 23, thereby reducing the circuit layout.

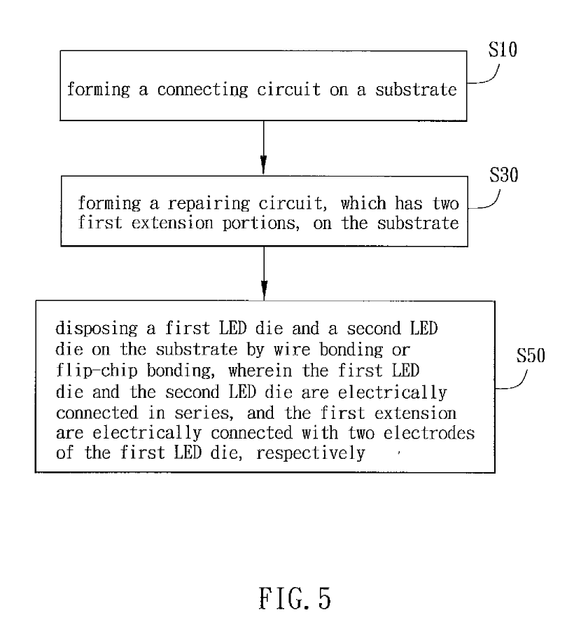

FIG. 5 is a flow chart of a manufacturing method of the LED package module according to the preferred embodiment of the invention. Referring to FIG. 5, the manufacturing method of the LED package module includes the steps of: forming a connecting circuit on a substrate (step S10); forming a repairing circuit, which has two first extension portions, on the substrate (step S30); and disposing a first LED die and a second LED die on the substrate by wire bonding or flip-chip bonding (step S50). The first LED die and the second LED die are electrically connected in series, and the first extension portions are electrically connected with two electrodes of the first LED die, respectively.

Since the manufacturing method of the LED package module of the invention has been described in the illustration of the LED package module 2 according to the previous embodiment, the detailed description thereof will be omitted.

In summary, the LED package module has the repairing circuit for bypassing the damaged LED die, so that the problem of the conventional LED package module that one damaged LED die can fail the entire LED package module can be prevented. In practice, each LED die can be detected through the repairing circuit so as to determine whether the LED die can emit light or not. If it is detected that one LED die is damaged, the extension portions of the repairing circuit corresponding to the damaged LED die are shorted, so that the current can bypass the damaged LED die and the other LED dies can operate normally. Thus, the LED package module with one or few damaged LED dies can still work and will not be regarded as a defect product. Accordingly the present invention can increase the manufacturing yield of the LED package module, reduce the cost and prevent the waste of the material.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting diode (LED) package module, comprising:
a substrate;
a first LED die disposed on the substrate by wire bonding or flip-chip bonding;
a second LED die disposed on the substrate by wire bonding or flip-chip bonding;
a connecting circuit, wherein the first LED die and the second LED die are electrically connected in series through the connecting circuit; and
a repairing circuit having two first extension portions, wherein the first extension portions are electrically connected with two electrodes of the first LED die, respectively.

2. The LED package module according to claim 1, further comprising:
a package body covering the first LED die and the second LED die, wherein the repairing circuit is partially exposed from the package body.

3. The LED package module according to claim 1, wherein the repairing circuit further has two first repairing pads, and each of the two first repairing pads is disposed on one end of each of the first extension portions away from the first LED die.

4. The LED package module according to claim 3, wherein the first extension portions are electrically connected with the electrodes of the first LED die through the connecting circuit.

5. The LED package module according to claim 3, wherein the repairing circuit further has two extension portions electrically connected with two electrodes of the second LED die, respectively.

6. The LED package module according to claim 5, wherein one of the second extension portions and one of the first extension portions are combined together.

7. The LED package module according to claim 5, wherein the repairing circuit further has two second repairing pads, and each of the second repairing pads is disposed on one end of each of the second extension portions away from the second LED die.

8. A manufacturing method of a LED package module, comprising steps of:
forming a connecting circuit on a substrate;
forming a repairing circuit on the substrate, wherein the repairing circuit has two first extension portions; and
disposing a first LED die and a second LED die on the substrate by wire bonding or flip-chip bonding, wherein the first LED die and the second LED die are electrically connected in series, and the first extension portions are electrically connected with two electrodes of the first LED die, respectively.

9. The manufacturing method according to claim 8, further comprising a step of:
disposing a package body to cover the first LED die and the second LED die, wherein the repairing circuit is partially exposed from the package body.

10. The manufacturing method according to claim 8, further comprising a step of
shorting the first extension portions when detecting that the first LED die is damaged.

11. The manufacturing method according to claim 10, wherein the step of shorting the first extension portions is performed by soldering, wiring, connecting with a low-resistance element, or laser welding through a vertical overlap area of the repairing circuit.

12. The manufacturing method according to claim 8, wherein the repairing circuit further has two first repairing pads, and each of the two first repairing pads is disposed on one end of each of the first extension portions away from the first LED die.

13. The manufacturing method according to claim 8, wherein the first extension portions are electrically connected with the electrodes of the first LED die through the connecting circuit.

14. The manufacturing method according to claim 8, wherein the repairing circuit further has two extension portions electrically connected with two electrodes of the second LED die, respectively.

15. The manufacturing method according to claim 14, wherein one of the second extension portions and one of the first extension portions are combined together.

16. The manufacturing method according to claim 14, wherein the repairing circuit further has two second repairing pads, and each of the second repairing pads is disposed on one end of each of the second extension portions away from the second LED die.
